(19) United States
(12) Patent Application Publication
(10) Pub. No.: US 2021/0218382 A1
(43) Pub. Date: Jul. 15, 2021

(54) N-PATH BANDSTOP FILTER WITH EXTENDED SPURIOUS-FREE UPPER PASSBAND

(71) Applicant: BAE Systems Information and Electronic Systems Integration Inc., Nashua, NH (US)

(72) Inventor: Mark D. Hickle, Merrimack, NH (US)

(73) Assignee: BAE Systems Information and Electronic Systems Integration Inc., Nashua, NH (US)

(21) Appl. No.: 16/738,441

(22) Filed: Jan. 9, 2020

(51) Int. Cl. H03H 7/01; H03H 7/00; H03H 11/04

(52) U.S. Cl. CPC H03H 7/0153; H03H 7/004; H03H 2007/013; H03H 2011/0488; H03H 11/0466

(57) ABSTRACT

Techniques are disclosed for filtering a radio frequency (RF) signal using an N-path bandstop filter with an extended, spurious-free upper passband. In an embodiment, a bandstop filter includes a bank of three switched capacitors in series with the RF signal path through the filter, in contrast to 4- or 8-capacitor banks or other bandstop filters where N is a power of 2. In this 3-path example configuration, an undesirable spurious bandstop notch at the 3^{rd} and 5^{th} harmonics of the clock frequency are eliminated or substantially reduced, improving performance of the filter in the desired passbands while preserving the notch in the desired stopband at high RF signal frequencies. Another N-path bandstop filter embodiment includes a bridged T-coil circuit, which absorbs a shunt capacitance of the bandstop filter into the bridged T-coil circuit.

### STATEMENT OF GOVERNMENT INTEREST

This invention was made with United States Government assistance under Contract No. HR0011-17-C-0005 awarded by DARPA. The United States Government has certain rights in this invention.

### FIELD OF THE DISCLOSURE

This disclosure relates generally to the field of signal filtering, and more particularly, to techniques for filtering a radio frequency (RF) signal using an N-path bandstop filter.

### BACKGROUND

Wideband receivers are used in various applications, such as advanced electronic warfare systems, communication systems, and radar systems. Wideband receivers provide the flexibility and reconfigurability to adapt to unpredictable and rapidly-changing spectral environments. Tunable bandstop filters are useful components which allow a receiver to selectively suppress strong interference or jamming signals while allowing the reception of weak signals of interest. These filters must have narrow stopbands to effectively reject interferers and jammers, and broad passbands to allow reception of desired signals over a broad frequency range. An N-path bandstop filter is a type of filter having a small form-factor and wide turnability, but as will be appreciated in light of this disclosure, existing configurations do not have the required broad passband due to certain drawbacks. Thus, improved filtering techniques are needed.

### BRIEF DESCRIPTION OF THE DRAWINGS

FIG. 1 is a schematic diagram of a single-ended N-path bandstop filter susceptible to spurious stop bands, impedance mismatch and insertion loss degradation.

FIG. 2 is a timing diagram of an example clock waveform for use with the single-ended N-path bandstop filter of FIG. 1.

FIG. 3 is a schematic diagram of a differential N-path bandstop filter that is susceptible to spurious stop bands, impedance mismatch and insertion loss degradation.

FIG. 4 is a schematic diagram of a differential 8-path bandstop filter that is susceptible to spurious stop bands, impedance mismatch and insertion loss degradation.

FIG. 5 is a timing diagram of an example clock waveform for use with the differential 8-path bandstop filter of FIG. 4.

FIG. 6 shows a simulated response of the differential 8-path bandstop filter of FIG. 4.

FIG. 7 is a schematic diagram of an example differential 3-path bandstop filter, in accordance with an embodiment of the present disclosure.

FIG. 8 shows example clock waveforms for controlling the 3-path bandstop filter of FIG. 7, in accordance with an embodiment of the present disclosure.

FIG. 9 shows a simulated response of the 3-path bandstop filter of FIG. 7, in accordance with an embodiment of the present disclosure.

FIG. 10 is a block diagram of an example clock waveform generator configured to generate the example clock waveforms of FIG. 8, in accordance with an embodiment of the present disclosure.

FIG. 11 shows example output clock waveforms produced by the clock waveform generator of FIG. 10, in accordance with an embodiment of the present disclosure.

FIG. 12 is a schematic diagram of another example differential 3-path bandstop filter, in accordance with another embodiment of the present disclosure.

FIG. 13 shows a simulated response of the bandstop filter of FIG. 12, in accordance with an embodiment of the present disclosure.

FIG. 14 shows an example bridged T-coil circuit, in accordance with an embodiment of the present disclosure.

FIG. 15 shows an example bandstop filter with a bridged T-coil circuit, in accordance with another embodiment of the present disclosure.

FIG. 16 shows a simulated response of the bandstop filter of FIG. 15, in accordance with an embodiment of the present disclosure.

FIG. 17 is a flow diagram of an example process for filtering a radio frequency (RF) signal using an N-path bandstop filter circuit, in accordance with an embodiment of the present disclosure.

### DETAILED DESCRIPTION

Techniques are disclosed for filtering a radio frequency (RF) signal using an N-path bandstop filter. The techniques are particularly useful for applications that benefit from an extended, spurious-free upper passband. In accordance with an embodiment of the present disclosure, a 3-path bandstop filter includes a bank of three switched capacitors in series with the RF signal path through the filter. In this 3-path configuration, undesirable spurious bandstop notches at the 3rd and 5^{th} harmonics of the clock frequency are eliminated or otherwise sufficiently softened such that they do not remove or otherwise overly attenuate signals of interest, thereby improving performance of the filter in the desired passbands while preserving the notch in the desired stopband at high RF signal frequencies. In some other embodiments, an N-path bandstop filter includes a bridged T-coil circuit, which absorbs a shunt capacitance of the bandstop filter into the bridged T-coil circuit. Other embodiments and variations will be evident in view of this disclosure.

General Overview

A broadband RF front-end used with a radio receiver is prone to interfering or jamming signals (collectively referred to herein as jamming signals, for brevity). An RF pre-select or bandstop filter can be used to block or suppress certain frequencies from passing from the antenna to the receiver. For example, as previously noted, tunable bandstop filters allow a receiver to selectively suppress the strength of strong jamming signals while increasing the dynamic range of the receiver to allow reception of weak signals of interest. One type of tunable bandstop filter is an N-path bandstop or notch filter. N-path bandstop filters include a bank of switched capacitors in series with the RF signal path. When the capacitors are switched or commutated at a clock rate f_{clk} by actuating the switches with non-overlapping control signals, a bandstop filtering transfer function is created with a center frequency equal to or near f_{clk}. In general, an N-path filter eliminates or significantly reduces the N^{th} harmonic spurious notch. For example, an N-path filter where N=3 eliminates or significantly reduces the 3^{rd} harmonic notch, N=4 eliminates or significantly reduces the 4^{th} harmonic notch, N=7 eliminates or significantly reduces the 7^{th} harmonic notch, and so on. However, certain N-path bandstop filter configurations are passband limited at some clock rates for several reasons. For instance, certain N-path bandstop filters, particularly where N is a power of two, such as N=4 or N=8, can have spurious stopbands (or notches) at even or odd harmonics of the fundamental stopband frequency. These spurious stopbands degrade the filter's upper passband and are therefore undesirable in wideband applications. Furthermore, there are many sources of shunt capacitance in an N-path bandstop filter, and these sources can cause non-trivial impedance mismatch and insertion loss degradation in some high frequency passbands. Thus, some N-path bandstop filter configurations can be upper-passband-limited and less suitable for high frequency, wideband operations.

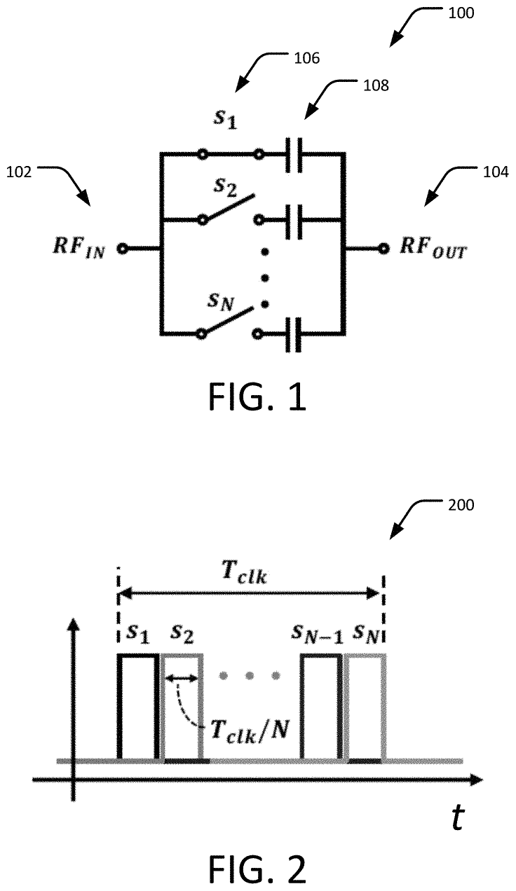

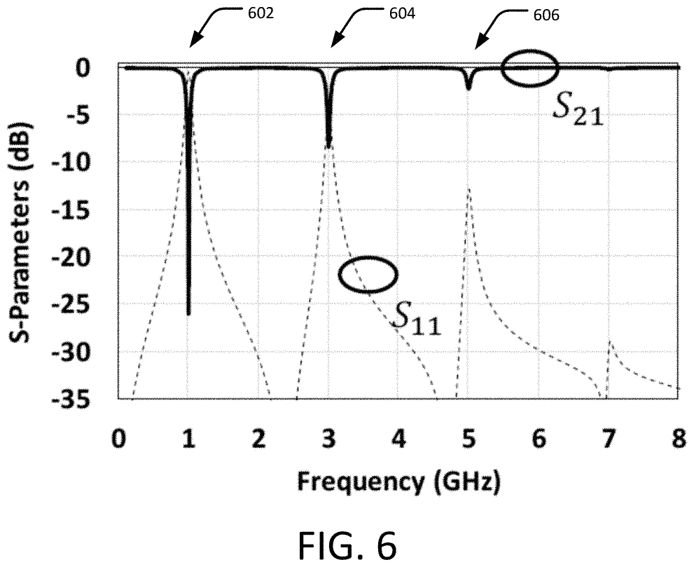

In more detail, FIG. 1 is a schematic diagram of a single-ended N-path bandstop filter 100 that is susceptible to spurious stop bands, impedance mismatch and insertion loss degradation, which will be further explained with reference to FIG. 6. The bandstop filter 100 receives an RF input signal 102 and produces an RF output signal 104. The bandstop filter 100 includes N switches 106 and N capacitors 108, where N is any integer. The switches 106 are labeled in FIG. 1 as S₁, S₂, . . . , S_{N}. The switches 106 and the capacitors 108 are in series with an RF signal path from the input 102 to the output 104. Thus, each of the N RF signal paths includes at least one switch 106 and at least one capacitor 108. FIG. 2 is a timing diagram of an example clock waveform 200 for use with the bandstop filter 100 of FIG. 1. The switches 106 are operated at a clock frequency of f_{clk} using non-overlapping control signals, such as shown in FIG. 2, where one switch 106 is closed at a given time instant t and the width of each clock pulse that closes the respective switch 106 is T_{clk}/N, which is also referred to in this disclosure as the duty cycle of the clock pulse.

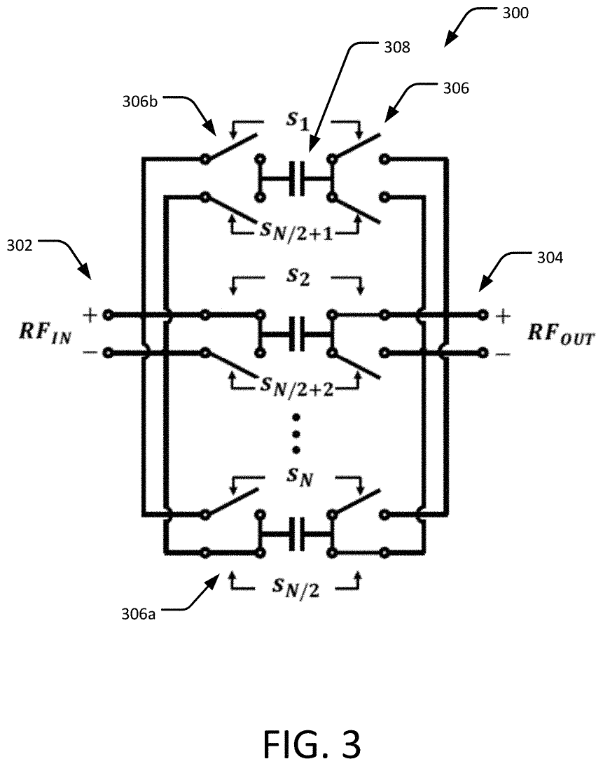

FIG. 3 is a schematic diagram of a differential N-path bandstop filter 300 that is susceptible to spurious stop bands, impedance mismatch and insertion loss degradation, which will be further explained with reference to FIG. 6. The clock waveform 200 of FIG. 2 can be used to control the switches of the bandstop filter 300 of FIG. 3 when Nis a power of 2, such as N=4 or N=8. The bandstop filter 300 receives positive (+) and negative (−) RF input signals 302 and produces positive and negative RF output signals 304. The bandstop filter 300 includes 2N switch pairs 306a, 306b and N capacitors 308, where Nis a power of 2, including N=2, 4, 8, 16, etc. The switch pairs 306a, 306b are labeled in FIG. 3 as S₁, S_{N/2+1}, S₂, S_{N/2+2}, . . . , S_{N}, and S_{N/2}. For example, the two switches labelled S₁ on either side of the capacitor 308 represent one switch pair associated with the capacitor 308. The switch pairs 306a and corresponding capacitors 308 are in series with the positive RF signal path from the input 302 to the output 304. The switch pairs 306b and corresponding capacitors 308 are in series with the negative RF signal path from the input 302 to the output 304. The switch pairs 306a, 306b are replicated (paired) on both sides of the capacitors 308 to prevent back-feeding them when the switches on the input side are open. The switch pairs 306a, 306b are operated at a clock frequency of f_{clk} using non-overlapping control signals, such as shown in FIG. 2, where one switch pair 306a, 306b is closed at a given time instant t and the width of each clock pulse that closes the respective switch pair 306a, 306b is T_{clk}/N.

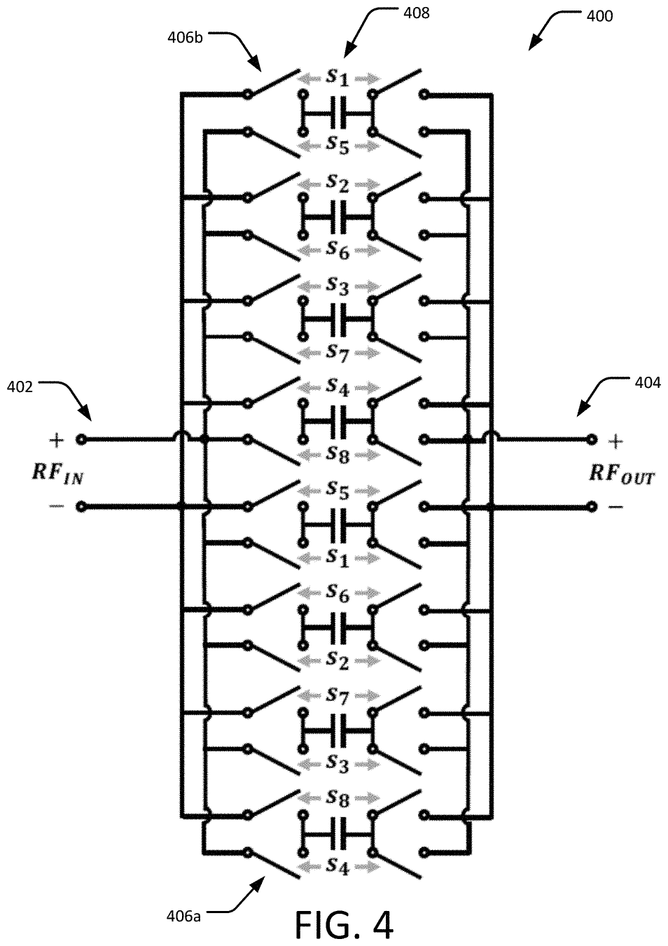

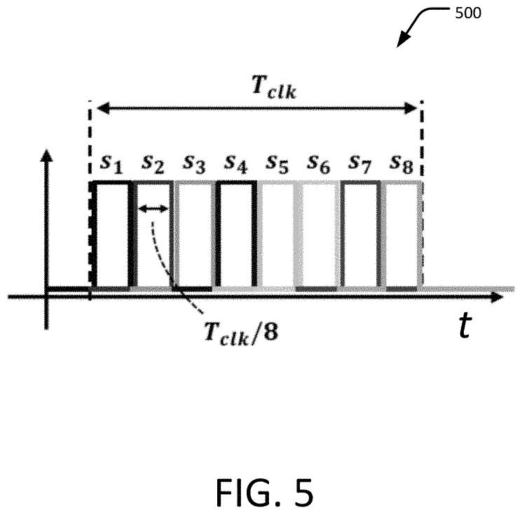

FIG. 4 is a schematic diagram of a differential 8-path bandstop filter 400 that is susceptible to spurious stop bands, impedance mismatch and insertion loss degradation, which will be further explained with reference to FIG. 6. The bandstop filter 400 receives positive (+) and negative (−) RF input signals 402 and produces positive and negative RF output signals 404. The bandstop filter 400 includes sixteen switch pairs 406a, 406b and eight capacitors 408. The switch pairs 406a, 406b are labeled in FIG. 4 as S₁, S₅, S₂, S₆, S₃, S₇, S₄, S₈, S₅, S₁, S₆, S₂, S₇, S₃, S₈, and S₄. For example, switch pair S₁ represents one switch pair associated with one or more of the capacitors 408. Note that each switch pair 406a, 406b may be connected to more than one of the capacitors 408, such as schematically shown in FIG. 4. The switch pairs 406a and corresponding capacitors 408 are in series with the positive RF signal path from the input 402 to the output 404. The switch pairs 406b and corresponding capacitors 408 are in series with the negative RF signal path from the input 402 to the output 404. The switch pairs 406a, 406b are replicated (paired) on both sides of the capacitors 408 to prevent back-feeding them when the switches on the input side are open. FIG. 5 is a timing diagram of an example clock waveform 500 for use with the bandstop filter 400 of FIG. 4. The switch pairs 406a, 406b are operated at a clock frequency of f_{clk} using non-overlapping control signals, such as shown in FIG. 5, where one switch pair 406a, 406b is closed at a given time instant t and the width of each clock pulse that closes the respective switch pair 406a, 406b is T_{clk}/8.

FIG. 6 shows a simulated response of the bandstop filter 400 of FIG. 4 when the filter is operated at a clock frequency of 1 GHz. The vertical axis of the chart represents the scattering parameters or S-parameters of the bandstop filter 400 operating in a steady state, and the horizontal axis represents the RF signal input frequency. The S-parameters show the transfer function of the bandstop filter 400 as the input signal frequency is varied. In this configuration, the bandstop filter 400 has a fundamental bandstop transfer function centered at f_{clk}, indicated 602, as well as spurious notches centered at odd harmonics of the clock frequency 3 f_{clk}, 5 f_{clk}, which are indicated at 604 and 606, respectively. These spurious stopbands 604, 606 are detrimental in wideband receivers that are intended to receive signals of interest having frequencies at or near the spurious stopbands. In addition to blocking undesired signals at the center frequency of the notch 602, the filter attenuates or otherwise blocks signals which reside at multiples of the center frequency, such as the odd harmonics at notches 604, 606. The problem is even more challenging in single-ended N-path notch filters (FIG. 1), which possess spurious stopbands at both even and odd harmonics of the clock frequency.

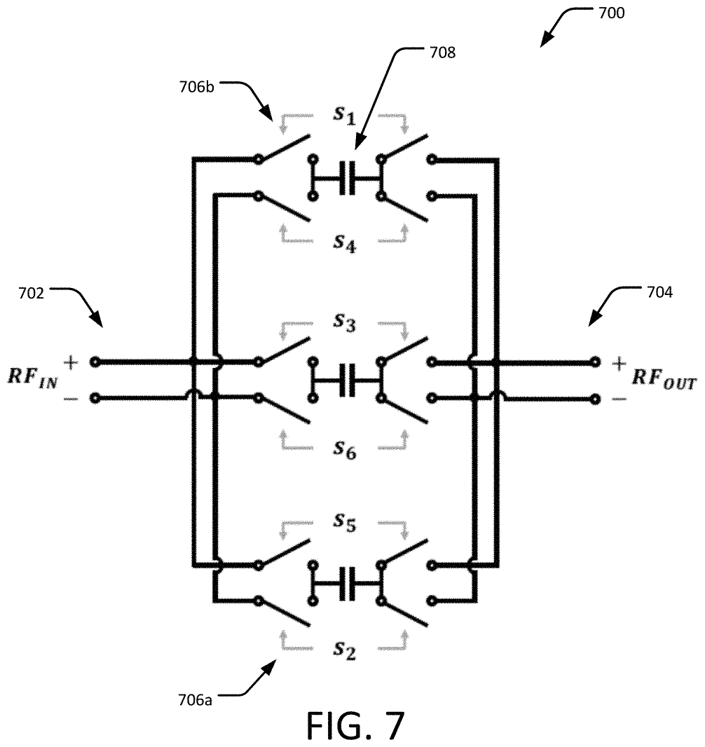

Therefore, there are several non-trivial issues associated with such filters in broadband RF receiver applications with respect to eliminating or otherwise sufficiently suppressing spurious stopbands, such as those indicated at 604 and 606 in FIG. 6. Some embodiments of the present disclosure address such issues, as will now be explained in turn with respect to FIGS. 7 through 17.

Example Differential N-Path Bandstop Filter and Switching Scheme

FIG. 7 is a schematic diagram of an example differential N-path bandstop filter 700, in accordance with an embodiment of the present disclosure. In this example, N=3. The 3^{rd} harmonic notch is a prominent and problematic spurious notch. As noted above, an N-path filter where N=3 eliminates or significantly reduces the 3^{rd} harmonic notch. While certain other values of N (such as the 8-path bandstop filter 400 of FIG. 4) can be used, according to an embodiment of the present disclosure, it is notable that the spurious notches in the upper passband (e.g., at the 3^{rd} and 5^{th} harmonics of the clock frequency, such as shown in FIG. 6) are eliminated or significantly reduced when N=3, as compared to bandpass filters where N=4 or 8, or where N is any other power of 2. Note that it is not always necessary to completely eliminate a given spurious notch. Rather, in some applications it is sufficient to soften or reduce the spurious notches so as to not overly attenuate possible signals of interest. Thus, a sufficiently eliminated or softened spurious notch or stopband will not attenuate a possible signal of interest below a detectability threshold suitable for a given application (e.g., the signal of interest is still detectable, after having passed through the notch filter). Further note that a spurious-free filter is not intended to be limited to situations where there is absolutely no spurious signal in a given frequency band. Rather, spurious-free includes filters where some frequencies of interest are attenuated below a suitable threshold (e.g., to provide a desired spurious-free dynamic range).

In more detail, and with further reference to the example embodiment of FIG. 7, the bandstop filter 700 includes a bank of three switched capacitors 708. This 3-path configuration contrasts with a 4- or 8-capacitor bank configuration, such as shown in FIG. 4 for several reasons including the elimination or reduction of spurious notches at the 3rd and 5^{th} harmonics caused by the 4- and 8-path configurations. The bandstop filter 700 receives positive (+) and negative (−) RF input signals 702 and produces positive and negative RF output signals 704. The bandstop filter 700 includes twelve switches arranged in six switch pairs 706a, 706b and three capacitors 708 in series with the respective switch pairs 706a, 706b. The switch pairs 706a, 706b are labeled as S₁, S₄, S₃, S₆, S₅, and S₂. For example, the two switches S₁ on either side of the capacitor 708 represents one switch pair associated with the capacitor 708. The switch pairs 706a and corresponding capacitors 708 are in series with the positive RF signal path from the input 702 to the output 704. The switch pairs 706b and corresponding capacitors 708 are in series with the negative RF signal path from the input 702 to the output 704. The switch pairs 706a, 706b are replicated (paired) on both sides of the capacitors 708 to prevent back-feeding them when the switches on the input side are open.

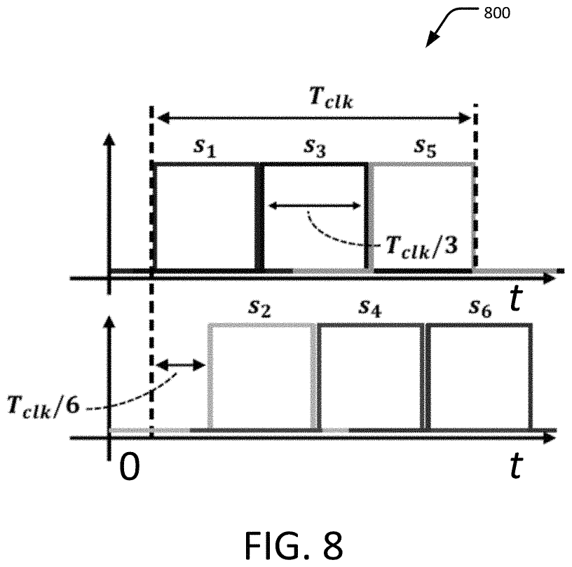

FIG. 8 shows example clock waveforms for controlling the switches of the N-path bandstop filter 700 of FIG. 7, in accordance with an embodiment of the present disclosure. As can be seen, the switches 706a, 706b are operated at a clock frequency of f_{clk} using overlapping control signals, where one or two switches 806a, 806b are closed at a given time instant t and the width of each clock pulse that closes the respective switch 806a, 806b is T_{clk}/3. The N-path filter 700 utilizes six clock pulses, where each pulse has a 33.3% (⅓) duty cycle. Each of the pulses, when high, causes the corresponding switch to close (for a normally open switch). For example, as shown in FIG. 8, switch S₁ is closed between time t=0 and t=T_{clk}/6. Between time t=T_{clk}/6 and t=2 (T_{clk}/6), switches S₁ and S₂ are closed. Between time t=2 (T_{clk}/6) and t=3 (T_{clk}/6), switches S₂ and S₃ are closed. Between time t=3 (T_{clk}/6) and t=4 (T_{clk}/6), switches S₃ and S₄ are closed. Between time t=4 (T_{clk}/6) and t=5 (T_{clk}/6), switches S₄ and S₅ are closed. Between time t=5 (T_{clk}/6) and t=T_{clk}, switches S₅ and S₆ are closed. This operation contrasts with the operation of 4- or 8-path filters, which require 4 or 8 clock phases with 25% (¼) or 12.5% (⅛) duty cycles, respectively, such as shown in FIGS. 2 and 5. The ⅓ duty cycle of the clock provides an advantage of a 3-path filter over 4- or 8-path filters because the associated clock waveforms have broader pulse widths and therefore can be synthesized at higher frequencies.

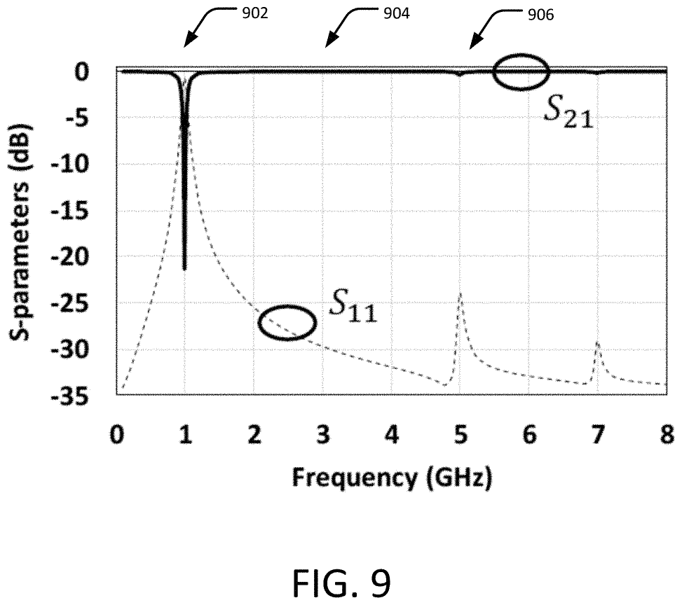

FIG. 9 shows a simulated response when the bandstop filter 700 of FIG. 7 is operated at a clock frequency of 1 GHz, in accordance with an embodiment of the present disclosure. The vertical axis of the chart represents the scattering parameters or S-parameters of the bandstop filter 700 operated in a steady state, and the horizontal axis represents the RF signal input frequency. The S-parameters show the transfer function of the bandstop filter 700 as the input signal frequency is varied. In this configuration, the bandstop filter 700 has a fundamental bandstop transfer function centered at f_{clk}, indicated at 902. However, as shown in FIG. 9, the 3^{rd} harmonic spurious stopband notch 904 at the clock frequency 3 f_{clk} has been eliminated and the 5^{th} harmonic spurious stopband notch 906 at the clock frequency 5 f_{clk} has been reduced to approximately −0.3 dB, which in many cases can be considered as negligible.

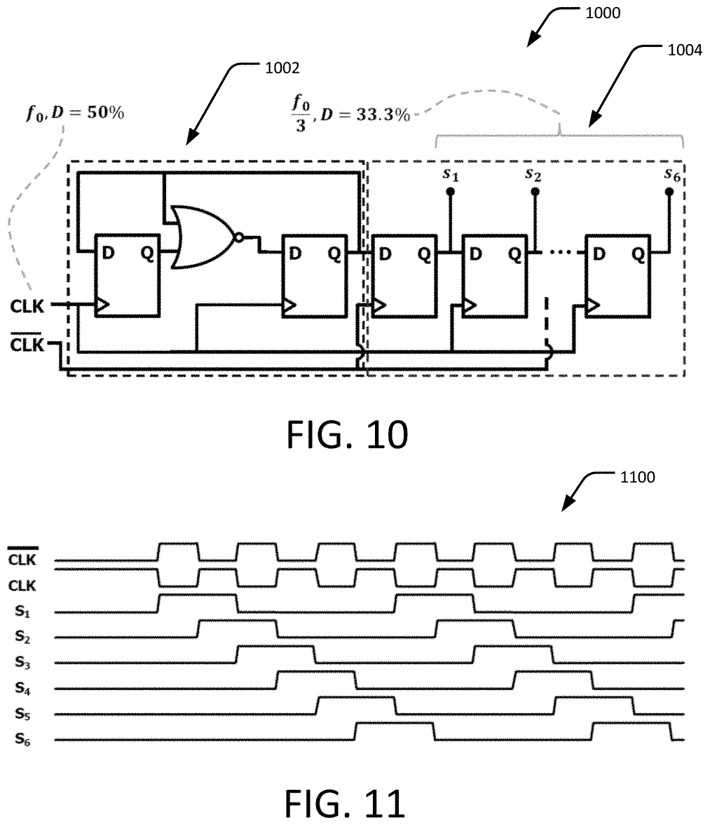

FIG. 10 is a block diagram of an example clock waveform generator 1000 configured to generate the example clock waveforms of FIG. 8, in accordance with an embodiment of the present disclosure. The clock waveform generator 1000 is configured to generate the six clock phases of FIG. 8 with 33.3% (⅓) duty cycle for controlling operation (opening and closing) of the switches S₁ through S₆. The first block 1002 of the generator 1000 divides the frequency of an input clock CLK by a factor of three. The input to this block is a clock with a frequency of 3f₀ and a 50% duty cycle, and the output of this block is a clock with a frequency of f₀ and a 33.3% duty cycle. The second block 1004 of the generator 1000 includes a shift register which generates the six clock phases from the output of the first block 1002 (i.e., the clock with a frequency of f₀ and a 33.3% or ⅓ duty cycle). The shift register includes six D flip-flops in series, where each successive flip-flop is clocked alternatingly with either the rising or falling edge of the input clock CLK, which has a frequency of 3f₀, to set the state of the output of the first block 1002 into the flip-flop. The output of the second block 1004 is six clock pulses (phases), each of which is successively delayed by

$$\frac{1}{6 {f}_{0}} ,$$

with frequencies equal to f₀ and duty cycles equal ⅓, such as shown in the example output clock waveforms 1100 of FIG. 11.

Example Bandstop Filter with Bridged T-Coil Circuit

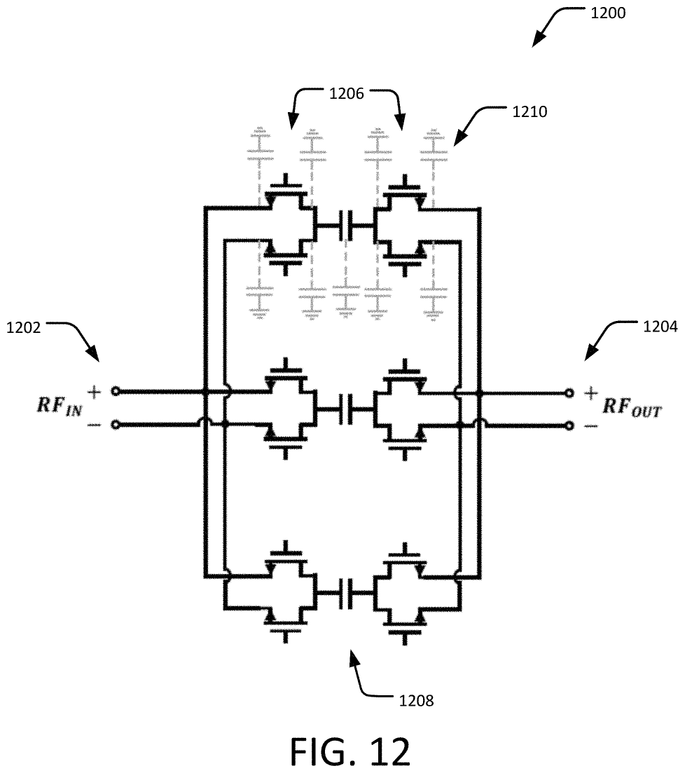

FIG. 12 is a schematic diagram of another example differential N-path bandstop filter 1200, in accordance with an embodiment of the present disclosure. In some embodiments, N=3. However, regardless of N, the bandstop filter 1200 can have many switches 1206 and large capacitors 1208 in series with the RF signal path, and thus the bandstop filter 1200 has many sources of shunt parasitic capacitances 1210. An illustration of some of the sources of parasitic capacitances is shown in FIG. 12, in which the switches 306a, 306b of the filter 300 of FIG. 3 have been implemented in the bandstop filter 1200 as n-type metal oxide semiconductor (NMOS) transistors 1206 located between the RF signal input 1202 and the RF signal output 1204. The parasitic capacitances 1210 arise from the gate-drain and gate-source overlap capacitance in the transistors 1206 and from the shunt capacitance from the bottom plates of the capacitors 1208 to the substrate of the physical circuit. At high frequencies, such as frequencies greater than 1 GHz, these parasitic capacitances 1210 degrade the insertion loss and return loss of the RF signal passing through the bandstop filter 1200.

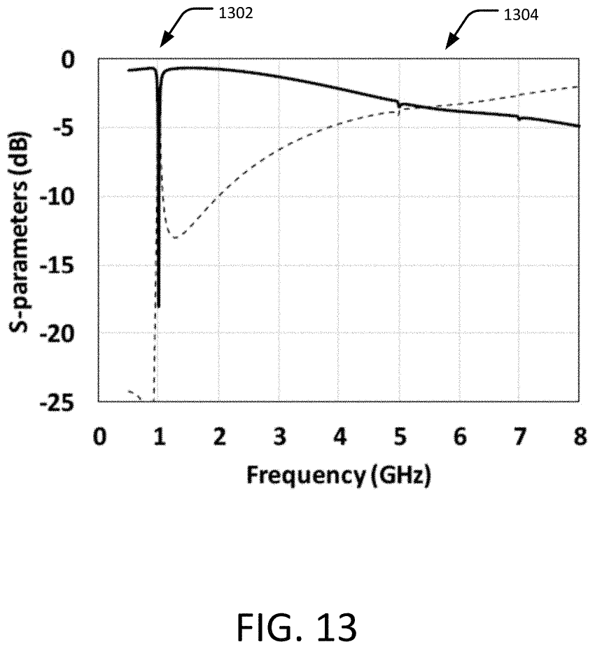

FIG. 13 shows the simulated response when the bandstop filter 1200 of FIG. 12 is operated at a clock frequency of 1 GHz. The vertical axis of the chart represents the scattering parameters or S-parameters of the bandstop filter 1200 operated in a steady state, and the horizontal axis represents the clock frequency. An example of the effect of the parasitic capacitances can be seen in FIG. 13, where the bandstop notch at 1 GHz is indicated at 1302. The vertical axis represents the scattering parameters or S-parameters of the bandstop filter 1200 operated in a steady state, and the horizontal axis represents the clock frequency. As shown in FIG. 13, the passband insertion loss and impedance match are both severely degraded at high frequencies (over 1 GHz), as indicated at 1304, due to the shunt parasitic capacitances of the bandstop filter 1200, as discussed above. In broadband systems, it is important to maintain a clean transmission response up to high frequencies, and thus it is desirable to compensate for the effect of the parasitic shunt capacitances to avoid degradation of the response, such as shown in FIG. 13.

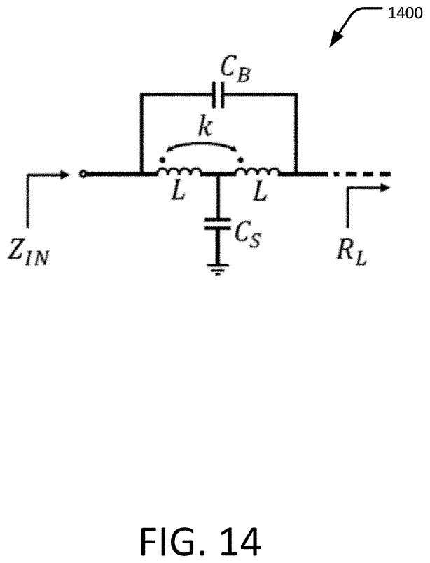

In accordance with an embodiment of the present disclosure, a very broadband impedance match can be maintained in the presence of a large shunt capacitance by absorbing the shunt capacitance of the bandstop filter into a bridged T-coil circuit. An example bridged T-coil circuit 1400 is represented schematically in FIG. 14. In this configuration, C_{S} represents the large, undesired shunt parasitic capacitance, and L and C_{B} are the additional elements added to neutralize the effect of the shunt capacitance. A perfect input impedance match can be obtained for all frequencies by choosing:

$$L = \frac{{C}_{S} {R}_{L}^{2}}{4} ( 1 + \frac{1}{4 {ζ}^{2}} ) , {C}_{B} = \frac{{C}_{L}}{16 {ζ}^{2}} , k = \frac{4 {ζ}^{2} - 1}{4 {ζ}^{2} + 1}$$

where ζ is a design parameter which affects the phase response of the circuit's transmission coefficient. The bridged T-coil circuit 1400 compensates for the strong shunt capacitances present in the N-path notch filter.

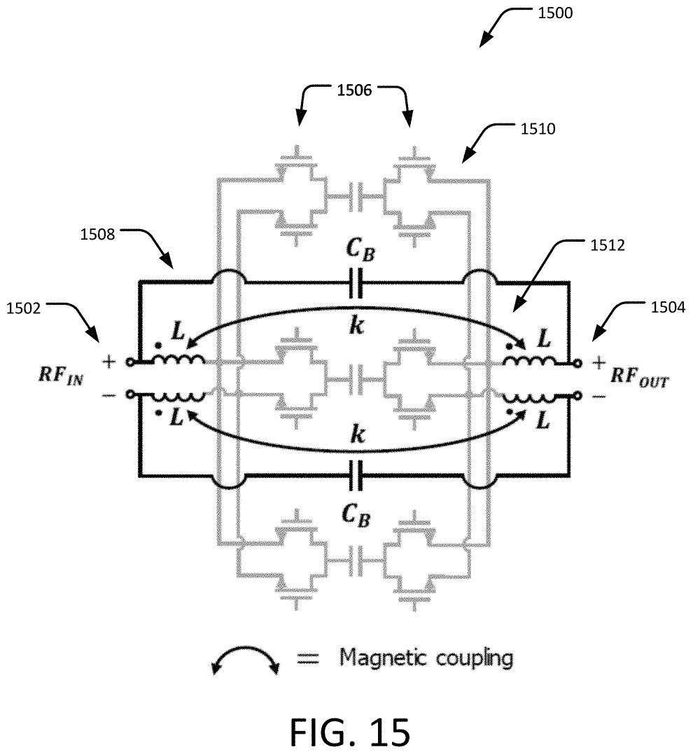

To this end, and in accordance with an embodiment of the present disclosure, a bridged T-coil circuit 1400 can be implemented with the shunt capacitance C_{S} replaced by an N-path filter circuit, such as shown in FIG. 15.

FIG. 15 shows an example bandstop filter with bridged T-coil circuit 1500, in accordance with an embodiment of the present disclosure. The bandstop filter 1500 includes a bridged T-coil circuit 1508 applied to a differential 3-path bandstop filter 1510. Although the example of FIG. 15 includes a 3-path bandstop filter, it will be understood that any N-path bandstop filter can be used in conjunction with the bridged T-coil circuit 1508, such as where N=4 or N=8. NMOS transistors 1506 are located between the RF signal input 1502 and the RF signal output 1504. Bridge inductors L are in series with the RF signal path from the input 1502 to the output 1504, both before and after the RF signal passes through the bandstop filter 1510. In this configuration, mutual magnetic coupling 1512 occurs between the inductors L at the input 1502 and the output 1504. A bridge capacitor C_{B} is connected from the input 1502 to the output 1504 of the bandstop filter 1510.

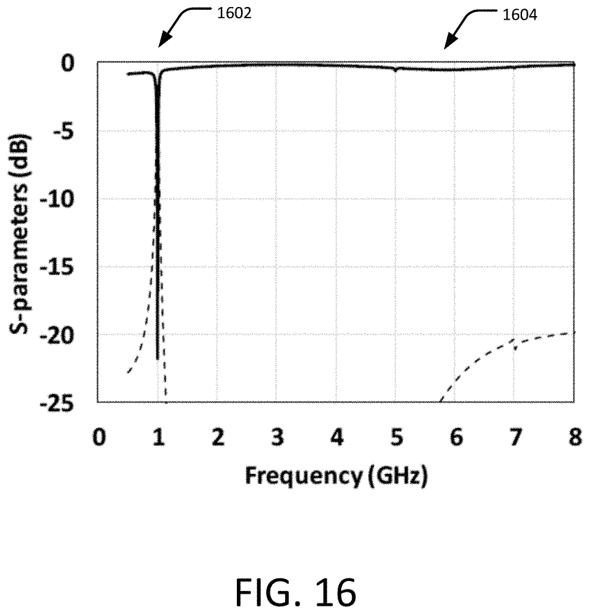

FIG. 16 shows the simulated response of the bandstop filter 1500 of FIG. 15. The vertical axis of the chart represents the scattering parameters or S-parameters of the bandstop filter 1500 operated in a steady state, and the horizontal axis represents the RF signal input frequency. As can be seen in FIG. 16, the insertion loss and return loss of the bandstop filter 1600 are greatly improved in the upper passband 1604 (approximately −0.3 dB) as compared to the response of the bandstop filter 1200 of FIG. 12 (without the bridged T-coil circuit), where the losses are about −5 dB, which in some cases can be considered as negligible.

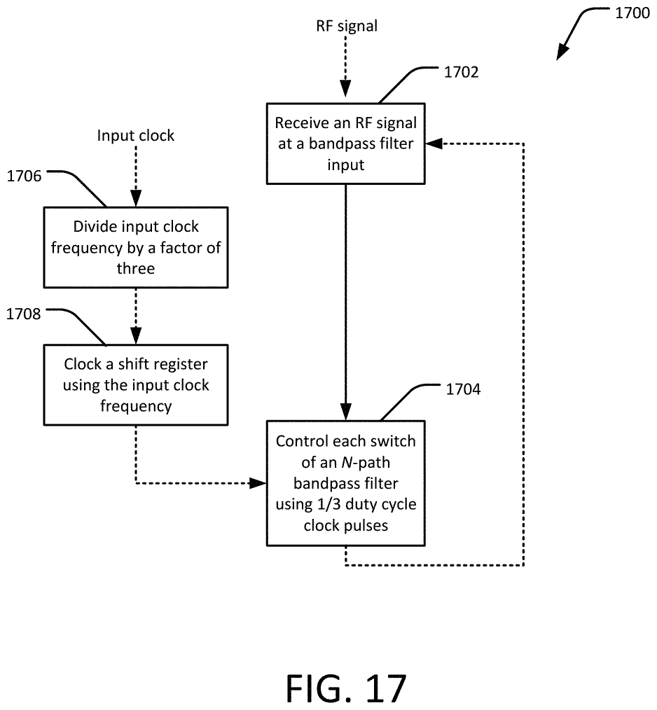

FIG. 17 is a flow diagram of an example process 1700 for filtering a radio frequency (RF) signal using an N-path bandstop filter circuit. The bandstop filter circuit includes at least three capacitors arranged in parallel and at least twelve switches arranged in at least six pairs, such as shown in FIGS. 7, 12 and 15. Each pair of switch pairs is arranged in series with one of the capacitors. The process 1700 includes receiving 1702 a radio frequency (RF) signal at a bandstop filter input connected to the bandstop filter circuit. The process 1700 further includes controlling 1704 each of the switches using one of a plurality of clock pulses, wherein each of the clock pulses has a ⅓ duty cycle, thus causing the bandstop filter to provide a filtered RF signal to a bandstop filter output connected to the bandstop filter circuit, such as shown and described with respect to FIGS. 7, 12 and 15. In some embodiments, the method 1700 includes dividing 1706 a frequency 3f₀ of an input clock by a factor of three, which provides a first clock with a frequency of f₀ and the ⅓ duty cycle, such as described with respect to the circuit 1000 of FIG. 10. In some such embodiments, the method 1700 further includes clocking 1708, using the input clock, a shift register having six flip-flops in series connected to the first clock, where each successive flip-flop is clocked alternatingly with either a rising edge of the input clock or a falling edge of the input clock. This provides at least six of the clock pulses for controlling each

$$\frac{1}{6 {f}_{0}} ,$$

of the switch pairs, where each of the clock pulses is successively delayed by such as shown in FIG. 11 (S₁ through S₆). In some embodiments, at least two of the clock pulses overlap for ⅙th of the duty cycle, such as shown in FIGS. 8 and 11. In some embodiments, the bandstop filter circuit includes exactly three capacitors, exactly twelve switches, and exactly six pairs of switches, such as in the bandstop filter 700 of FIG. 7. In some embodiments, each pair of switches (e.g., S₁ through S₆) is controlled by different ones of the clock pulses, such as shown in FIGS. 8 and 11. In some embodiments, the bandstop filter circuit includes a bridged T-coil circuit arranged between the bandstop filter input and the bandstop filter output. The bridged T-coil circuit includes at least two inductors in parallel with at least one capacitor, such as the bandstop filter 1500 of FIG. 15. In some embodiments, at least one of the switches includes a NMOS transistor, such as described with respect to the bandstop filter 1500 of FIG. 15.

Numerous embodiments will be apparent in light of the present disclosure, and features described herein can be combined in any number of configurations. One example embodiment provides a radio frequency (RF) filter circuit. The circuit includes a bandstop filter input and a bandstop filter output; a clock waveform generator configured to generate a plurality of clock pulses, each of the clock pulses having a ⅓ duty cycle; and a bandstop filter circuit connected between the bandstop filter input and the bandstop filter output. The bandstop filter circuit includes at least three capacitors arranged in parallel and a plurality of switches arranged in pairs, each pair of switches arranged in series with a respective one of the at least three capacitors, each of the switches configured to be controlled by one of the clock pulses. In some cases, the clock waveform generator is configured to divide a frequency 3f₀ of an input clock by a factor of three, thereby providing a first clock with a frequency of f₀ and the ⅓ duty cycle, and the clock waveform generator includes a shift register having six flip-flops in series connected to the first clock, where each successive flip-flop is clocked alternatingly with either a rising edge of the input clock or a falling edge of the input clock, thereby providing at least six of the clock pulses, each of which is successively delayed by

$$\frac{1}{6 {f}_{0}} .$$

In some cases, me bandstop filter circuit includes exactly three capacitors and at least six pairs of switches. In some cases, at least two of the clock pulses overlap for ⅙th of the duty cycle. In some cases, each pair of the switches is configured to be controlled by different ones of the clock pulses. In some cases, the circuit includes a bridged T-coil circuit arranged between the bandstop filter input and the bandstop filter output, the bridged T-coil circuit including at least two inductors in parallel with at least one bridge capacitor. In some such cases, at least one of the switches includes an n-type metal oxide semiconductor (NMOS) transistor.

Another example embodiment provides a radio frequency (RF) filter circuit. The circuit includes a bandstop filter input and a bandstop filter output; a bandstop filter circuit connected between the bandstop filter input and the bandstop filter output, the bandstop filter circuit including a plurality of capacitors arranged in parallel and a plurality of switches, each of the switches arranged in series with a respective one of the capacitors; and a bridged T-coil circuit arranged between the bandstop filter input and the bandstop filter output. The bridged T-coil circuit includes at least two bridge inductors in parallel with at least one bridge capacitor. In some cases, at least one of the switches includes an n-type metal oxide semiconductor (NMOS) transistor. In some cases, the circuit includes a clock waveform generator configured to generate a plurality of clock pulses, each of the clock pulses having a ⅓ duty cycle, where each of the switches is configured to be controlled by one of the clock pulses. In some such cases, the clock waveform generator is configured to divide a frequency 3f₀ of an input clock by a factor of three, thereby providing a first clock with a frequency of f₀ and the ⅓ duty cycle, and the clock waveform generator includes a shift register having six flip-flops in series connected to the first clock, where each successive flip-flop is clocked alternatingly with either a rising edge of the input clock or a falling edge of the input clock, thereby providing at least six of the clock pulses, each of which is successively delayed by

$$\frac{1}{6 {f}_{0}} .$$

In some other such cases, at least two of the clock pulses overlap for ⅙th of the duty cycle. In some cases, the bandstop filter circuit includes exactly three capacitors and at least six switches.

Yet another example embodiment provides a radio frequency (RF) filter circuit. The circuit includes a bandstop filter input and a bandstop filter output; a clock waveform generator configured to generate a plurality of clock pulses, each of the clock pulses having a fractional duty cycle; and a bandstop filter circuit connected between the bandstop filter input and the bandstop filter output. The bandstop filter circuit includes N capacitors arranged in parallel and a plurality of switches, each of the switches arranged in series with a respective one of the capacitors, each of the switches configured to be controlled by one of the clock pulses, where N is an odd integer and wherein at least two of the clock pulses overlap for a portion of the duty cycle. In some cases, the clock waveform generator is configured to divide a frequency Nf0 of an input clock by a factor of N, thereby providing a first clock with a frequency of f₀ and a 1/N duty cycle, and wherein the clock waveform generator includes a shift register having a plurality of flip-flops in series connected to the first clock, wherein each successive flip-flop is clocked alternatingly with either a rising edge of the input clock or a falling edge of the input clock, thereby providing at least two of the clock pulses, each of which is successively delayed at a frequency of 2Nf0. In some cases, the bandstop filter circuit includes exactly three capacitors and at least six switches. In some cases, at least two of the clock pulses overlap for ½N of the duty cycle. In some cases, at least two of the switches are configured to be controlled by different ones of the clock pulses. In some cases, the circuit includes a bridged T-coil circuit arranged between the bandstop filter input and the bandstop filter output, the bridged T-coil circuit including at least two bridge inductors in parallel with at least one bridge capacitor. In some cases, at least one of the switches includes an n-type metal oxide semiconductor (NMOS) transistor.

The foregoing description and drawings of various embodiments are presented by way of example only. These examples are not intended to be exhaustive or to limit the invention to the precise forms disclosed. Alterations, modifications, and variations will be apparent in light of this disclosure and are intended to be within the scope of the invention as set forth in the claims.

1. A radio frequency (RF) filter circuit comprising:
a bandstop filter input and a bandstop filter output;
a clock waveform generator configured to generate a plurality of clock pulses, each of the clock pulses having a ⅓ duty cycle; and
a bandstop filter circuit connected between the bandstop filter input and the bandstop filter output, the bandstop filter circuit including at least three capacitors arranged in parallel and a plurality of switches arranged in pairs, each pair of switches arranged in series with a respective one of the at least three capacitors, each of the switches configured to be controlled by one of the clock pulses.

2. The circuit of claim 1, wherein the clock waveform generator is configured to divide a frequency 3f₀ of an input clock by a factor of three, thereby providing a first clock with a frequency of f₀ and the ⅓ duty cycle, and wherein the clock waveform generator includes a shift register having six flip-flops in series connected to the first clock, wherein each successive flip-flop is clocked alternatingly with either a rising edge of the input clock or a falling edge of the input clock, thereby providing at least six of the clock pulses, each of which is successively delayed by
$$\frac{1}{6 {f}_{0}} .$$

3. The circuit of claim 1, wherein the bandstop filter circuit includes exactly three capacitors and at least six pairs of switches.

4. The circuit of claim 1, wherein at least two of the clock pulses overlap for ⅙^{th} of the clock pulses widths.

5. The circuit of claim 1, wherein each pair of the switches is configured to be controlled by different ones of the clock pulses.

6. The circuit of claim 1, further comprising a bridged T-coil circuit arranged between the bandstop filter input and the bandstop filter output, the bridged T-coil circuit including at least two inductors in parallel with at least one bridge capacitor.

7. The circuit of claim 1, wherein at least one of the switches includes an n-type metal oxide semiconductor (NMOS) transistor.

8. A radio frequency (RF) filter circuit comprising:
a bandstop filter input and a bandstop filter output;
a bandstop filter circuit connected between the bandstop filter input and the bandstop filter output, the bandstop filter circuit including a plurality of capacitors arranged in parallel and a plurality of switches, each of the switches arranged in series with a respective one of the capacitors;
a bridged T-coil circuit arranged between the bandstop filter input and the bandstop filter output, the bridged T-coil circuit including at least two bridge inductors in parallel with at least one bridge capacitor; and
a clock waveform generator configured to generate a plurality of clock pulses, each of the clock pulses having a ⅓ duty cycle, wherein each of the switches is configured to be controlled by one of the clock pulses.

9. The circuit of claim 8, wherein at least one of the switches includes an n-type metal oxide semiconductor (NMOS) transistor.

10. (canceled)

11. The circuit of claim 8, wherein the clock waveform generator is configured to divide a frequency 3f₀ of an input clock by a factor of three, thereby providing a first clock with a frequency of f₀ and the ⅓ duty cycle, and wherein the clock waveform generator includes a shift register having six flip-flops in series connected to the first clock, wherein each successive flip-flop is clocked alternatingly with either a rising edge of the input clock or a falling edge of the input clock, thereby providing at least six of the clock pulses, each of which is successively delayed by
$$\frac{1}{6 {f}_{0}} .$$

12. The circuit of claim 8, wherein at least two of the clock pulses overlap for ⅙^{th} of the clock pulses widths.

13. The circuit of claim 8, wherein the bandstop filter circuit includes exactly three capacitors and at least six switches.

14. A radio frequency (RF) filter circuit comprising:
a bandstop filter input and a bandstop filter output;
a clock waveform generator configured to generate a plurality of clock pulses, each of the clock pulses having a fractional duty cycle; and
a bandstop filter circuit connected between the bandstop filter input and the bandstop filter output, the bandstop filter circuit including N capacitors arranged in parallel and a plurality of switches, each of the switches arranged in series with a respective one of the capacitors, each of the switches configured to be controlled by one of the clock pulses, wherein N is an odd integer and wherein at least two of the clock pulses overlap for a portion of the clock pulses widths.

15. The circuit of claim 14, wherein the clock waveform generator is configured to divide a frequency Nf₀ of an input clock by a factor of N, thereby providing a first clock with a frequency of f₀ and a 1/N duty cycle, and wherein the clock waveform generator includes a shift register having a plurality of flip-flops in series connected to the first clock, wherein each successive flip-flop is clocked alternatingly with either a rising edge of the input clock or a falling edge of the input clock, thereby providing at least two of the clock pulses, each of which is successively delayed at a frequency of 2Nf₀.

16. The circuit of claim 14, wherein the bandstop filter circuit includes exactly three capacitors and at least six switches.

17. The circuit of claim 14, wherein at least two of the clock pulses overlap for ½N of the clock pulses widths.

18. The circuit of claim 14, wherein at least two of the switches are configured to be controlled by different ones of the clock pulses.

19. The circuit of claim 14, further comprising a bridged T-coil circuit arranged between the bandstop filter input and the bandstop filter output, the bridged T-coil circuit including at least two bridge inductors in parallel with at least one bridge capacitor.

20. The circuit of claim 14, wherein at least one of the switches includes an n-type metal oxide semiconductor (NMOS) transistor.
